(19) United States
(12) Patent Application Publication
(10) Pub. No.: US 2024/0071783 A1
(43) Pub. Date: Feb. 29, 2024

(54) APPARATUS FOR TREATING SUBSTRATE

(71) Applicant: PSK INC., Hwaseong-si (KR)

(72) Inventors: Kwang Sung YOO, Hwaseong-si (KR); Jong Chan LEE, Hwaseong-si (KR)

(73) Assignee: PSK INC., Hwaseong-si (KR)

(21) Appl. No.: 18/364,626

(22) Filed: Aug. 3, 2023

(30) Foreign Application Priority Data
Aug. 24, 2022 (KR) 10-2022-0106291

(51) Int. Cl. H01L 21/67; H01J 37/32; H01L 21/3065; H01L 21/683

(52) U.S. Cl. CPC H01L 21/67069; H01J 37/32449; H01J 37/32568; H01L 21/3065; H01L 21/6833

(57) ABSTRACT

The inventive concept provides a substrate treating apparatus. The substrate treating apparatus includes a housing having a treating space; a support unit configured to support a substrate at the treating space; and a gas supply unit configured to supply a gas which is excited to a plasma to the treating space, and wherein the support unit includes: a chuck supporting a center region of the substrate; and an edge electrode formed in a ring shape, and wherein the edge electrode includes: a body portion surrounding the chuck at an outer side of the chuck; and a protrusion portion formed protruding to an outer side of the body portion, and a hole is formed at the protrusion portion penetrating the protrusion portion and which exhausts an atmosphere of the treating space.

### CROSS-REFERENCE TO RELATED APPLICATIONS

A claim for priority under 35 U.S.C. § 119 is made to Korean Patent Application No. 10-2022-0106291 filed on Aug. 24, 2022, in the Korean Intellectual Property Office, the entire contents of which are hereby incorporated by reference.

### BACKGROUND

Embodiments of the inventive concept described herein relate to a substrate treating apparatus, more specifically, an apparatus for treating a substrate using a plasma.

A plasma refers to an ionized gas state consisting of ions, radicals, and electrons. The plasma is produced by a very high temperature, a strong electric field, or a high-frequency electromagnetic field. A semiconductor element manufacturing process includes an etching process or an ashing process of removing a thin film on a substrate using a plasma. The ashing process or the etching process is performed by colliding or reacting ion particles and radical particles contained in the plasma with a film on the substrate.

When treating the substrate using the plasma, as a region in which the plasma is generated increases, a pressure control in a corresponding region is difficult. In addition, as the region in which the plasma is generated increases, the more difficult it is to control a gas flow in the corresponding region. Accordingly, a gas uniformity in the region in which the plasma is generated decreases. As a result, it is difficult to excite a respective gas according to the process requirements in the region in which the plasma is generated if it is difficult to control a pressure, and a gas flow. That is, as the region in which the plasma is generated increases, a plasma density decreases. When the plasma density decreases, a processing efficiency of the substrate compared to an input time decreases.

### SUMMARY

Embodiments of the inventive concept provide a substrate treating apparatus for efficiently treating a substrate.

Embodiments of the inventive concept provide a substrate treating apparatus for generating a high density plasma at an edge region of a substrate.

Embodiments of the inventive concept provide a substrate treating apparatus for efficiently controlling a pressure and a gas flow at a region in which a plasma is generated.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing having a treating space; a support unit configured to support a substrate at the treating space; and a gas supply unit configured to supply a gas which is excited to a plasma to the treating space, and wherein the support unit includes: a chuck supporting a center region of the substrate; and an edge electrode formed in a ring shape, and wherein the edge electrode includes: a body portion surrounding the chuck at an outer side of the chuck; and a protrusion portion formed protruding to an outer side of the body portion, and a hole is formed at the protrusion portion penetrating the protrusion portion and which exhausts an atmosphere of the treating space.

In an embodiment, the protrusion portion and the body portion are formed integrally

In an embodiment, the protrusion portion is formed along a circumferential direction of the body portion.

In an embodiment, an outer circumference of the protrusion portion extends to a sidewall of the housing.

In an embodiment, an exhaust hole is formed at the housing to exhaust the atmosphere of the treating space, and the atmosphere of the treating space is exhausted while passing through the hole and the exhaust hole.

In an embodiment, a top surface of the protrusion portion is positioned at a same height as a top surface of the body portion.

In an embodiment, the protrusion portion is formed at a top end of the body portion, and the top surface of the protrusion portion and the top end of the body portion are formed stepped with respect to one another.

In an embodiment, the top surface of the protrusion portion is positioned lower than the top surface of the body portion.

In an embodiment, the top surface of the protrusion portion is formed inclined.

In an embodiment, the top surface of the protrusion portion is formed downwardly inclined toward the sidewall of the housing.

The inventive concept provides a substrate treating apparatus. The substrate treating apparatus includes a housing having a treating space; a support unit configured to support a substrate at the treating space; and a plasma source for generating a plasma at an edge region of a substrate supported on the support unit, and wherein the support unit includes: a chuck supporting a center region of the substrate; and an edge electrode formed in a ring shape and positioned below the edge region, and wherein the edge electrode includes: a body portion surrounding the chuck at an outer side of the chuck; and a protrusion portion having a through hole for exhausting an atmosphere of the treating space and which protrudes to an outer side of the body portion.

In an embodiment, the protrusion portion and the body portion are formed integrally.

In an embodiment, a top surface of the protrusion portion is positioned at a height which is substantially the same as a top surface of the body portion.

In an embodiment, the top surface of the protrusion portion is positioned at a different height from the top surface of the body portion.

In an embodiment, the top surface of the protrusion portion is positioned lower than the top surface of the body portion.

In an embodiment, the top surface of the protrusion portion is formed inclined.

In an embodiment, the top surface of the protrusion portion is formed upwardly inclined toward the body portion.

In an embodiment, the plasma source includes a top edge electrode positioned above the edge region.

The inventive concept provides a substrate treating apparatus. The substrate treating apparatus includes a housing having a treating space; a support unit configured to support a substrate at the treating space; and a gas supply unit configured to supply a gas to an edge region of a substrate supported on the support unit; and a top edge electrode positioned above the edge region, and wherein the support unit includes: a chuck supporting a center region of the substrate; and an edge electrode formed in a ring shape and positioned below the edge region, and wherein the edge electrode includes: a body portion surrounding the chuck at an outer side of the chuck; and a protrusion portion formed protruding to an outer side of the body portion, and a hole which is formed at the protrusion portion penetrating the protrusion portion and which exhausts an atmosphere of the treating space.

In an embodiment, the protrusion portion and the body portion are formed integrally.

According to an embodiment of the inventive concept, a substrate may be efficiently treated.

According to an embodiment of the inventive concept, a uniform plasma may be generated at an edge region of the substrate.

According to an embodiment of the inventive concept, a high density plasma may be generated at an edge region of a substrate.

According to an embodiment of the inventive concept, a pressure and a gas flow may be effectively controlled at a region in which a plasma is generated.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 schematically illustrates a substrate treating apparatus according to an embodiment of the inventive concept.

FIG. 2 schematically illustrates a process chamber according to an embodiment of

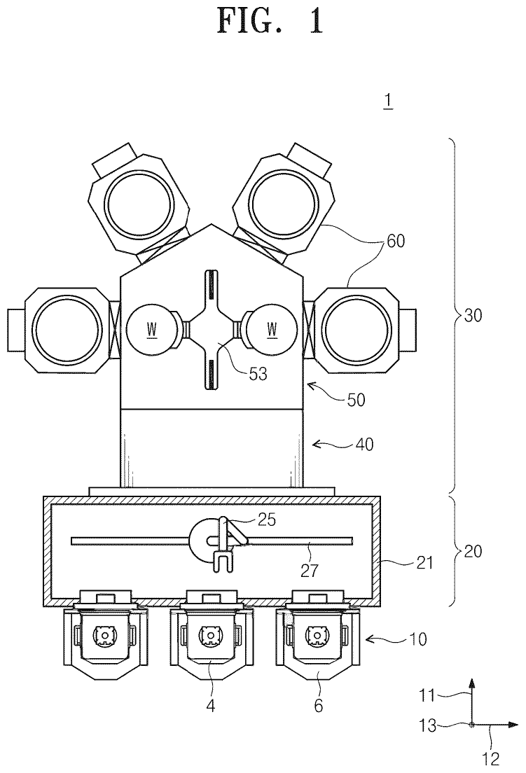

FIG. 1.

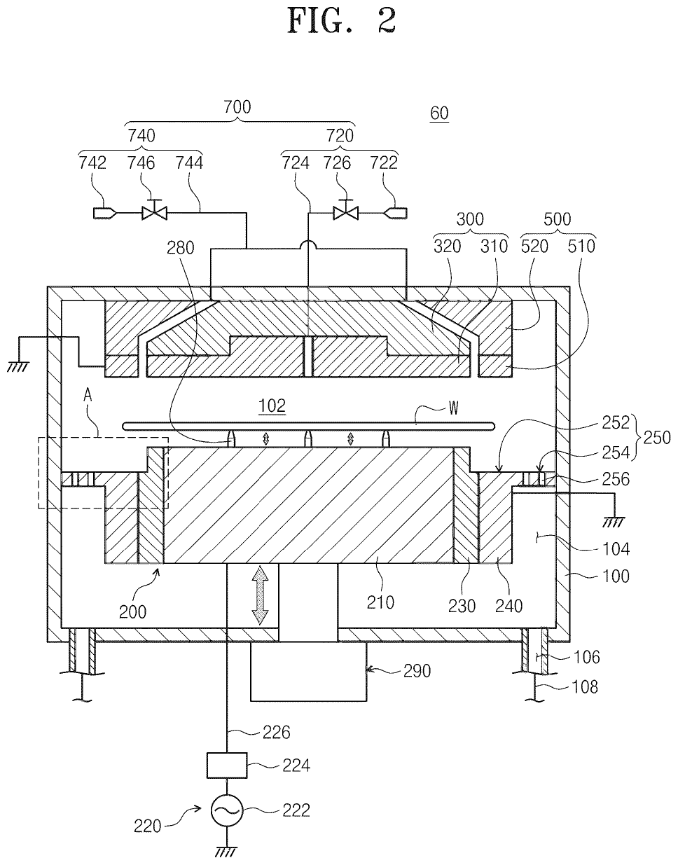

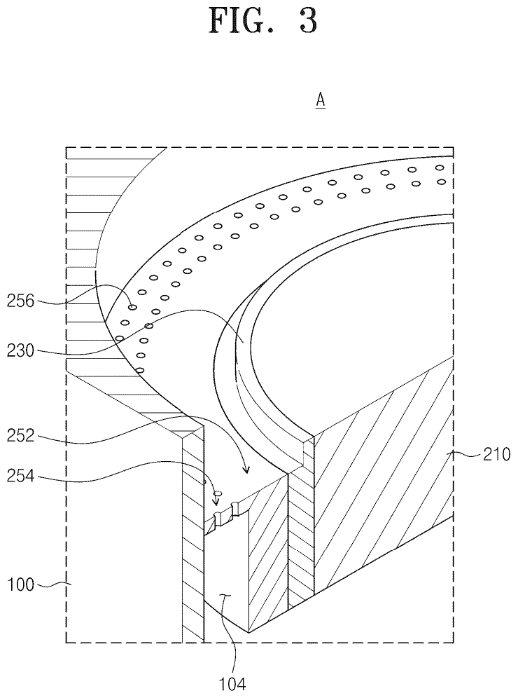

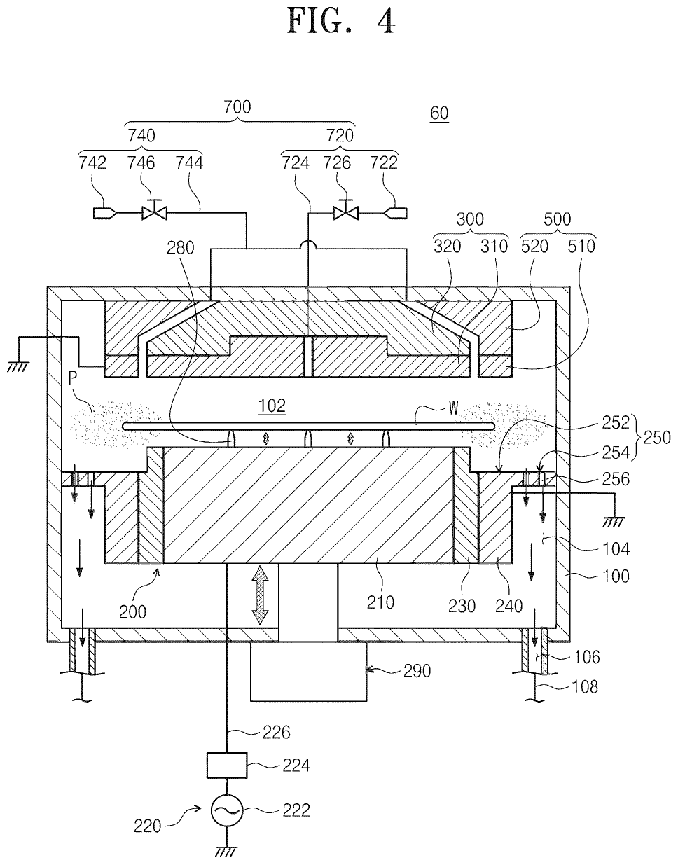

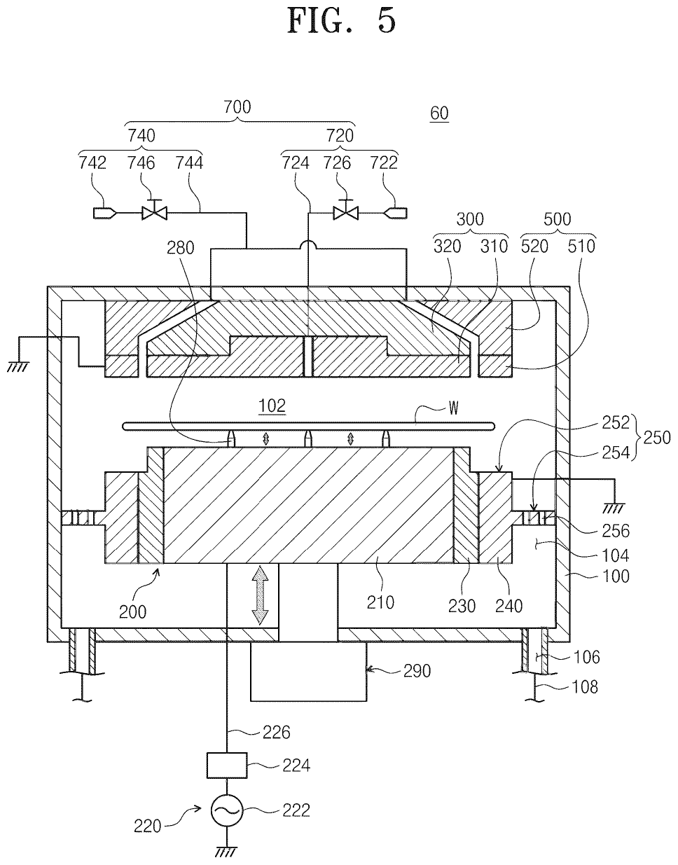

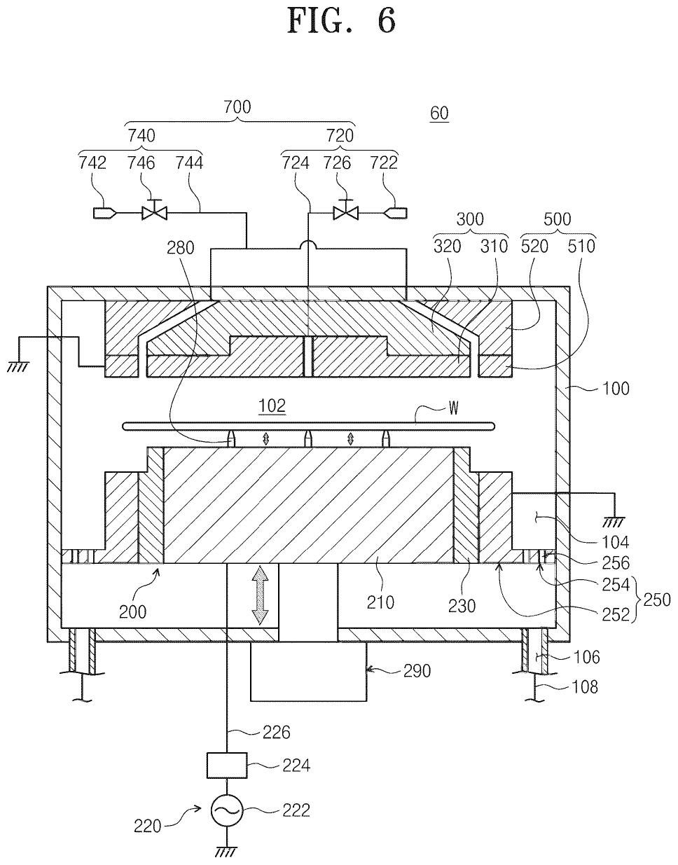

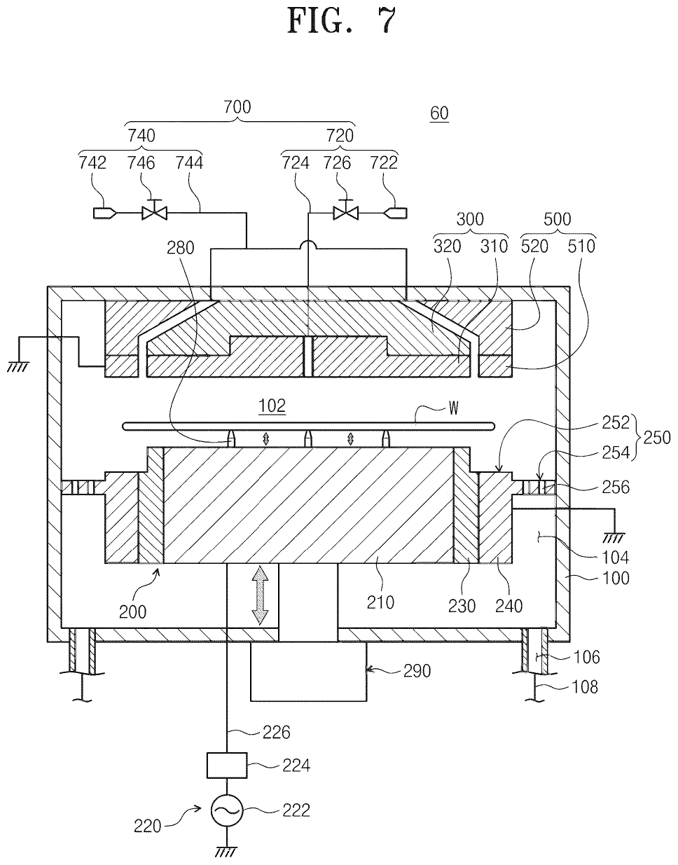

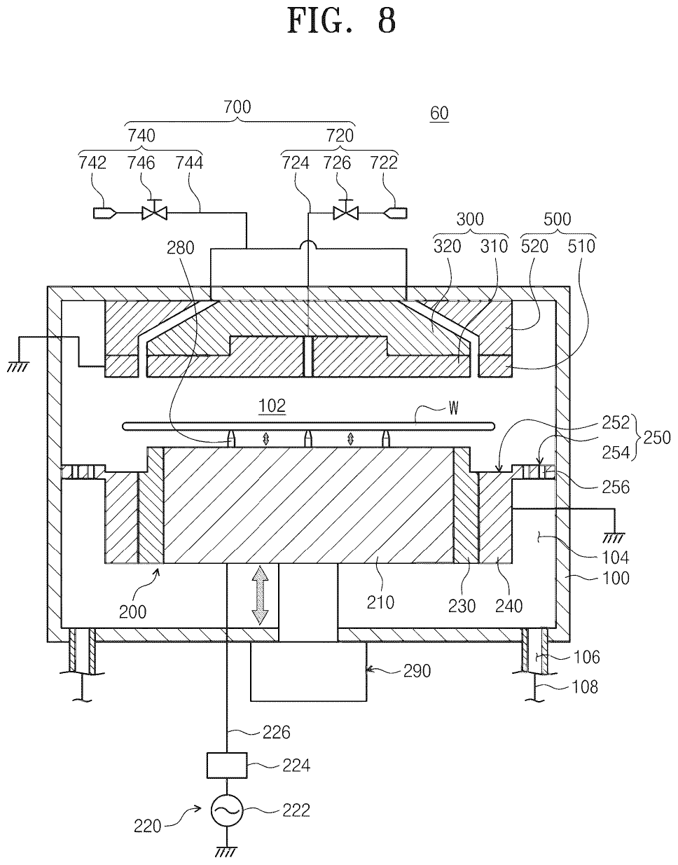

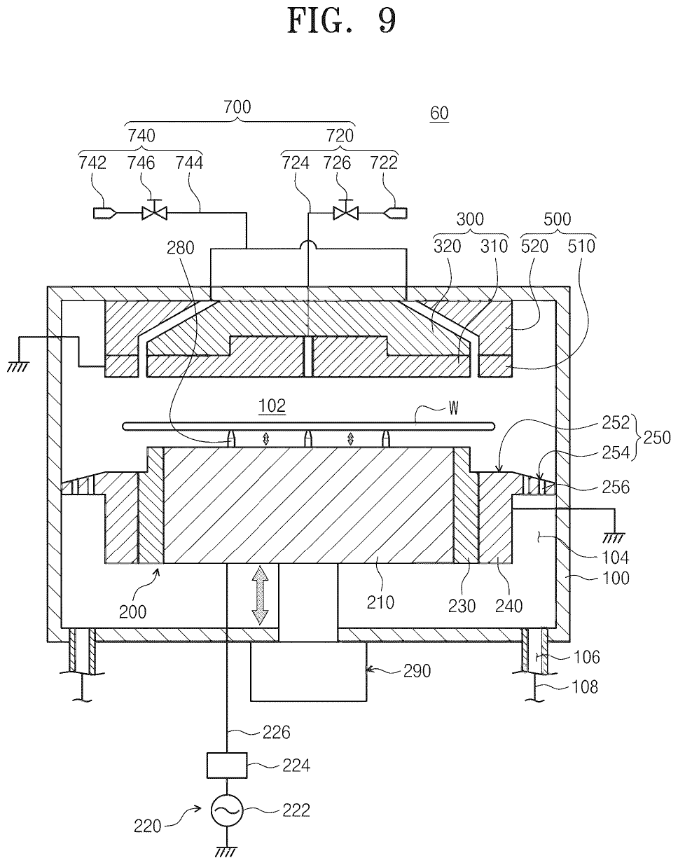

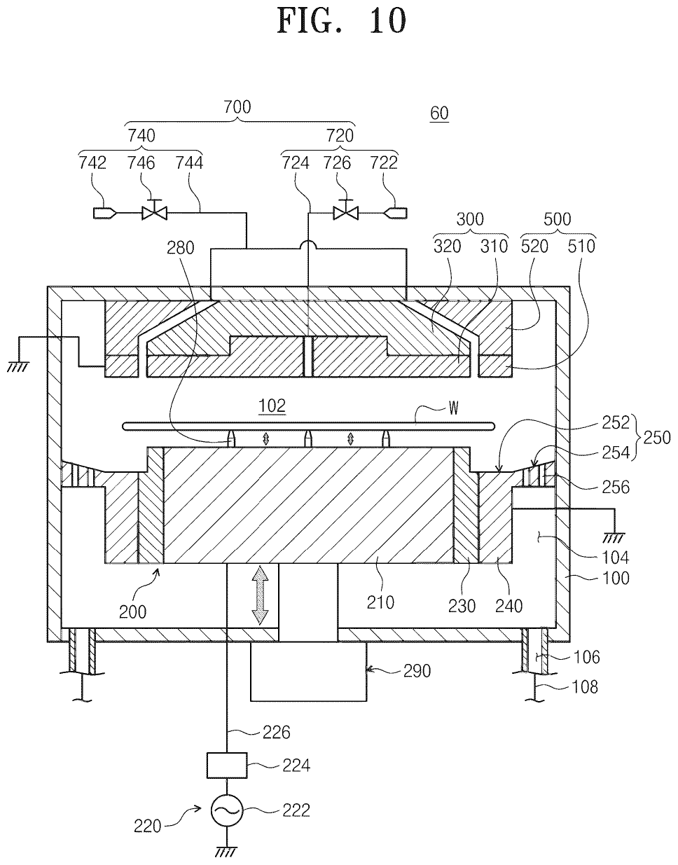

FIG. 3 is an enlarged perspective view of portion A of FIG. 2.

FIG. 4 schematically illustrates performing a plasma treatment process at the process chamber according to an embodiment of FIG. 2.

FIG. 5 to FIG. 10 schematically illustrate process chambers according to other embodiments of FIG. 1.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described in detail with reference to FIG. 1 to FIG. 10.

FIG. 1 schematically illustrates a substrate treating apparatus according to an embodiment of the inventive concept. Referring to FIG. 1, the substrate treating apparatus 1 has an Equipment Front End Module (EFEM) 20 and a treating module 30. The front end module 20 and the treating module 30 are disposed in a direction.

Hereinafter, a direction in which the front end module 20 and the treating module are disposed is defined as a first direction 11. In addition, when seen from above, a direction perpendicular to the first direction 11 is defined as a second direction 12. In addition, a direction perpendicular to a plane including both the first direction 11 and the second direction 12 is defined as a third direction 13. For example, the third direction 13 may be a direction perpendicular to the ground.

The front end module 20 has a load port 10 and a transfer frame 21. The load port has a plurality of support portions 6. A plurality of support portions 6 may be arranged in a row along the second direction 12. A container 4 may be seated on each support portion 6. The container 4 according to an embodiment may include a cassette, a FOUP, or the like. The container 4 may accommodate a substrate to be used in a process and a substrate on which a process has been completed.

The transfer frame 21 is disposed between the load port 10 and the treating module 30. The transfer frame 21 has an inner space. The inner space of the transfer frame 21 may be maintained in an atmospheric pressure atmosphere. A first transfer robot 25 is disposed inside the transfer frame 21. The first transfer robot 25 may move along the return rail 27 disposed in the second direction 12 to transfer the substrate between the container 4 and the treating module 30.

According to an embodiment, the treating module 30 may perform a treatment process of removing a thin film in an edge region of the substrate by receiving a substrate stored in the container 4 placed in the load port 10. The treating module 30 may include a load lock chamber 40, a transfer chamber 50, and a process chamber 60.

The load lock chamber 40 is disposed adjacent to the front end module 20. For example, the load lock chamber 40 may be disposed between the transfer frame 21 and the transfer chamber 50. The load lock chamber 40 has an inner space at which a substrate to be used in a process stands-by before being transferred to the process chamber 60 or before a substrate on which a process has been completed is transferred to the front end module 20. The inner space of the load lock chamber 40 may be switched between an atmospheric pressure atmosphere and a vacuum pressure atmosphere.

The transfer chamber 50 transfers the substrate. According to an embodiment, the transfer chamber 50 may transfer a substrate between the load lock chamber 40 and the process chamber 60. The transfer chamber 50 is disposed adjacent to the load lock chamber 40. The transfer chamber 50 may have a polygonal body when seen from above. A load lock chamber 40 and a plurality of process chambers 60 may be disposed along the circumference of the body outside the body.

The inside of the transfer chamber 50 may be generally maintained in a vacuum pressure atmosphere. Inside the transfer chamber 50, a second transfer robot 53 is placed between the load lock chamber 40 and the process chamber 60 to transfer the substrate. The second transfer robot 53 may transfer the untreated substrate waiting in the load lock chamber 40 to the process chamber 60, or transfer the substrate that has completed the predetermined process from the process chamber 60 to the load lock chamber 40. In addition, the second transfer robot 53 may transfer the substrate between the plurality of process chambers 60.

The process chamber 60 is disposed adjacent to the transfer chamber 50. A plurality of process chambers 60 may be provided. The plurality of process chambers 60 may be disposed along a circumference of the transfer chamber 50. In each of the process chambers 60, a predetermined process treatment is performed on the substrate. The process chamber 60 can receive the substrate from the second transfer robot 53, perform a predetermined process treatment on the substrate, and hand over a substrate on which the process treatment has been completed to the second transfer robot 53. A process treatment performed in each process chamber 60 may be different from each other.

Hereinafter, a process chamber 60 performing a plasma treatment process among the process chambers 60 will be described as an example. According to an embodiment, the process chamber 60 performing the plasma treatment process may etch or ash a film on the substrate. The film may include various types of films such as a polysilicon film, an oxide film, and a silicon nitride film. Selectively, the film may be a natural oxide film or a chemically produced oxide film. The film may be a foreign substance generated in a process of treating the substrate. /Selectively, the film may be a foreign substance attached to and/or remaining on a top surface and a bottom surface of the substrate.

In addition, the process chamber 60 which performs a plasma treatment process described below may be a chamber configured to perform a Bevel Etch process which removes a film on the edge region of the substrate among the process chambers 60 of the substrate treating apparatus 1. However, it is not limited to this, and the process chamber 60 of the substrate treating apparatus 1 described below can be applied equally or similarly to a chamber which performs various processes for treating the substrate. In addition, the process chamber 60 described below can be applied equally or similarly to various chambers in which the plasma treatment process on the substrate is performed.

FIG. 2 schematically illustrates a process chamber according to an embodiment of FIG. 1. Referring to FIG. 2, the process chamber 60 according to an embodiment may perform a process of removing a film formed on the substrate W using a plasma. For example, the process chamber 60 can supply a gas and process the edge region of the substrate W using the plasma generated by exciting a supplied gas.

The process chamber 60 may include a housing 100, a support unit 200, a dielectric unit 300, a top electrode unit 500, and a gas supply unit 700.

The housing 100 may be a chamber. According to an embodiment, the housing 100 may be a vacuum chamber. The housing 100 has a treating space 102 therein. The treating space 102 functions as a space in which the substrate W is treated. An opening (not shown) is formed on a sidewall of the housing 100. The substrate W may be taken into the treating space 102 through an opening (not shown) or may be taken out of the treating space 102. Although not shown, the opening (not shown) may be selectively opened and closed by a door assembly (not shown).

An exhaust hole 106 is formed on a bottom surface of the housing 100. The exhaust hole 106 may be connected to an exhaust line 108. The exhaust line 108 may be connected to a depressurizing member (not shown) applying a negative pressure.

FIG. 3 is an enlarged perspective view of portion A of FIG. 2. Hereinafter, a support unit according to an embodiment referring to FIG. 2 and FIG. 3 are illustrated in detail.

The support unit 200 is positioned in the treating space 102. The support unit 200 supports the substrate W in the treating space 102. The support unit 200 may include a chuck 210, a power member 220, a ring member 230 and an edge electrode 250.

The chuck 210 supports the substrate W in the treating space 102. The chuck 210 may have a substantially circular shape when seen from above. According to an embodiment, the top surface of the chuck 210 may have a diameter smaller than that of the substrate W. Accordingly, a center region of the substrate W supported by the chuck 210 is settled on the top surface of the chuck 210, and the edge region of the substrate W may not contact the top surface of the chuck 210. That is, in a state at which the center region of the substrate W is seated on the chuck 210, the edge region of the substrate W may be positioned on an outer region of the chuck 210.

A lift pin 280 may be positioned within the chuck 210. The lift pin 280 may lift and lower the substrate W. In addition, the driving member 290 may be coupled to the chuck 210. The driving member 290 may lift and lower the chuck 210.

A heater which is not shown may be positioned within the chuck 210. The heater (not shown) may heat the chuck 210 to adjust a temperature of the substrate W supported on the chuck 210. Also, a cooling fluid channel not shown may be formed within the chuck 210. A cooling fluid may flow within the cooling fluid channel (not shown). The cooling fluid cools the chuck 210 while flowing within the cooling fluid channel (not shown), thereby controlling a temperature of the substrate W supported by the chuck 210. A configuration for cooling the chuck 210 is not limited to a configuration for supplying the cooling fluid, and can be modified into various configurations (e.g., a cooling plate, etc.) capable of cooling the chuck 210.

The power member 220 supplies a power to the chuck 210. The power member 220 may include a power source 222, a matching device 224, and a power line 226. The power source 222 according to an embodiment may be a bias power source. In addition, the power source 222 may be an RF power source. The power source 222 may be connected to the chuck 210 through the power line 226. The matching device 224 may be installed on the power line 226 to perform an impedance matching.

The ring member 230 may have a ring shape. The ring member 230 may be disposed between the chuck 210 and the edge electrode 250 to be described later. The ring member 230 may be disposed along a circumference of the chuck 210. The ring member 230 may be disposed to surround an outer circumferential surface of the chuck 210 when seen from above. According to an embodiment, a top surface of the ring member 230 may be stepped. For example, a top surface of an inner portion of the ring member 230 may have a height higher than that of a top surface of an outer portion. According to an embodiment, the top surface of the inner portion of the ring member 230 may be positioned at a height corresponding to the top surface of the chuck 210. In addition, the top surface of the outer portion of the ring member 230 may be positioned at a height lower than the top surface of the chuck 210. Accordingly, the edge region of the substrate W seated on the top surface of the chuck 210 may be supported on the top surface of the inner portion of the ring member 230. That is, the top surface of the inner portion of the ring member 230 may support a bottom surface of the edge region of the substrate W. However, the inventive concept is not limited thereto, and the top surface of the ring member 230 may be generally flat.

The edge electrode 250 may be formed in a ring shape. The edge electrode 250 may be disposed to surround the ring member 230 when viewed from above. The edge electrode 250 functions as a plasma source. A detailed description of this will be described later. The edge electrode 250 may include a body portion 252 and a protrusion portion 254. According to an embodiment, the body portion 252 and the protrusion portion 254 may be integrally formed. In addition, a material of the body portion 252 and the protrusion portion 254 may be the same.

The body portion 252 may be disposed in the edge region of the substrate W supported by the chuck 210 when viewed from above. According to an embodiment, the edge electrode 250 may be disposed below the edge region of the substrate W. The body portion 252 may have a ring shape. The body portion 252 may be disposed to surround an outer circumferential surface of the ring member 230. Specifically, an inner circumferential surface of the body portion 252 may be disposed to surround the outer circumferential surface of the ring member 230. Accordingly, the body portion 252 may surround the chuck 210 outside the chuck 210. In addition, the outer circumferential surface of the body portion 252 may be disposed to be spaced apart from the sidewall of the housing 100 by a predetermined distance.

A space (hereinafter, the separation space) formed between the outer circumferential surface of the body portion 252 and the sidewall of the housing 100 can function as a space at which an atmosphere of the treating space 102 is exhausted. Specifically, the separation space 104 may function as a space in which a gas supplied into the treating space 102 is exhausted. In addition, the separation space 104 can function as a space which discharges foreign substances generated in a process of treating the substrate W which are floating in the treating space 102. In addition, the separation space 104 may function as a space for adjusting a pressure of the treating space 102. A hole 256 to be described later may be positioned above the separation space 104. In addition, the above-described exhaust hole 106 may be positioned below the separation space 104.

According to an embodiment, a top surface of the body portion 252 may be disposed to have a height corresponding to a top surface of the outer portion of the ring member 230. However, the inventive concept is not limited thereto, and the height of the top surface of the body portion 252 and the top surface of the outer portion of the ring member 230 may be different.

The protrusion portion 254 may have a ring shape. The protrusion portion 254 may be integrally formed with the body portion 252. The protrusion portion 254 may be formed along a circumferential direction of the body portion 252. The protrusion portion 254 may be formed to protrude from the body portion 252. The protrusion portion 254 may be formed to protrude from the outside of the body portion 252. According to an embodiment, the protrusion portion 254 may protrude in a direction toward the sidewall of the housing 100. According to an embodiment, an outer circumferential surface of the protrusion portion 254 may extend to a sidewall of the housing 100. For example, the outer circumferential surface of the protrusion portion 254 may be in contact with an inner sidewall of the housing 100. Selectively, the outer circumferential surface of the protrusion portion 254 may be in contact with a liner (not shown) disposed within the housing 100. When viewed from above, an inner circumferential surface of the protrusion portion 254 may overlap the outer circumferential surface of the body portion 252. In addition, when viewed from above, the protrusion portion 254 may overlap the above-described separation space 104.

According to an embodiment, the protrusion portion 254 may be formed in a top portion of the body portion 252. According to an embodiment, the top surface of the protrusion portion 254 may be disposed at a height corresponding to the top surface of the body portion 252. For example, the top surface of the protrusion portion 254 and the top surface of the body portion 252 may be positioned on the same plane.

A plurality of holes 256 may be formed in the protrusion portion 254. According to an embodiment, the hole 256 may penetrate a top surface and a bottom surface of the protrusion portion 254. That is, the hole 256 may be a through hole. The holes 256 may be formed to be spaced apart from each other by a predetermined interval along a circumferential direction of the protrusion portion 254. In addition, the holes 256 may be formed in a plurality of rows along the circumferential direction of the protrusion portion 254. According to an embodiment, the hole 256 may have a circular cross section. However, the inventive concept is not limited thereto, and the hole 256 may be formed in the slit shape in the protrusion portion 254.

According to an embodiment, at least one of the body portion 252 and the protrusion portion 254 may be grounded. Accordingly, the edge electrode 250 may function as a plasma source. The edge electrode 250 may function as a plasma source which generates the plasma in the edge region of the substrate W by exciting the gas supplied to the treating space 102 together with the top edge electrode 510 to be described later.

Referring to FIG. 2, the dielectric unit 300 may include a dielectric plate 310 and a first base 320. A bottom surface of the dielectric plate 310 may be disposed to face the top surface of the chuck 210. The top surface of the dielectric plate 310 may be formed to be stepped so that a height of a center region is relatively higher than a height of an edge region. The bottom surface of the dielectric plate 310 may be formed in a substantially flat shape.

A gas fluid channel connected to a first gas supply unit 720 to be described later may be formed in the dielectric plate 310. A discharge end of the gas fluid channel may be disposed at a position corresponding to the center region of the substrate W supported by the chuck 210 when seen from above. For example, a first gas discharged through the discharge end of the gas fluid channel may be supplied to the center region of the substrate W supported by the chuck 210.

The first base 320 may be disposed between the dielectric plate 310 and a top wall of the housing 100. A diameter of the first base 320 may gradually increase from a top to a bottom. A diameter of a top surface of the first base 320 may be relatively smaller than a diameter of a bottom surface of the dielectric plate 310. A diameter of a bottom surface of the first base 320 may correspond to a diameter of the top surface of the dielectric plate 310. The top surface of the first base 320 may have a flat shape. In addition, the bottom surface of the first base 320 may have a shape corresponding to the top surface of the dielectric plate 310.

The top electrode unit 500 may include a top edge electrode 510 and a second base 520. When seen from above, the top edge electrode 510 may be disposed to overlap the edge region of the substrate W supported by the chuck 210. The top edge electrode 510 may be disposed above the substrate W when viewed from the front.

The top edge electrode 510 may be grounded. As described above, the top edge electrode 510 is grounded and functions as a plasma source together with the edge electrode 250. For example, the top edge electrode 510 may be a plasma source which generates a plasma by exciting a gas supplied to the edge region of the substrate W.

The top edge electrode 510 may be formed in a ring shape. The top edge electrode 510 may have a shape surrounding the dielectric plate 310 when seen from above. The top edge electrode 510 may be disposed to be spaced apart from the dielectric plate 310 by a predetermined distance. A separation space may be formed between the top edge electrode 510 and the dielectric plate 310. The separation space may function as a channel through which the gas flows. For example, the separation space may function as a part of a gas channel through which the second gas supplied from the second gas supply unit 740 to be described later flows. A discharge end of the separation space may be disposed at a position corresponding to the edge region of the substrate W supported by the chuck 210 when seen from above. For example, a gas discharged through the discharge end of the separation space may be supplied to the edge region of the substrate W supported by the chuck 210.

The second base 520 may be disposed above the chuck 210. The second base 520 may fix a position of the top edge electrode 510. The second base 520 may be disposed between the top edge electrode 510 and the top wall of the housing 100. The second base 520 may have a ring shape. The second base 520 may be disposed to be spaced apart from the first base 320. The second base 520 may be spaced apart from the first base 320 to form a separation space. The separation space may function as a channel through which a gas flows. For example, the separation space may function as a part of a gas channel through which the second gas supplied from the second gas supply unit 740 to be described later flows.

A separation space formed by combining the top edge electrode 510 and the dielectric plate 310 and a separation space formed by combining the second base 520 and the first base 320 may fluidly communicate with each other to function as a gas channel. The second gas supplied from the second gas supply unit 740 may be supplied to the edge region of the substrate W through the gas channel.

The gas supply unit 700 supplies a process gas to the treating space 102. The gas supply unit 700 may include a first gas supply unit 720 and a second gas supply unit 740.

The first gas supply unit 720 may supply the first gas to the treating space 102. For example, the first gas may be an inert gas including a nitrogen. The first gas supply unit 720 may supply the first gas to the center region of the substrate W supported by the chuck 210. The first gas supply unit 720 may include a first gas supply source 722, a first gas supply line 724, and a first valve 726.

The first gas supply source 722 may store the first gas. An end of the first gas supply line 724 may be connected to the first gas supply source 722, and the other end thereof may be connected to a fluid channel formed in the dielectric plate 310. The first valve 726 is installed in the first gas supply line 724. The first valve 726 may be an on/off valve or a flow rate control valve. The first gas may be supplied to the center region of the substrate W through the fluid channel formed in the dielectric plate 310.

The second gas supply unit 740 supplies the second gas to the treating space 102. The second gas supply unit 740 may include a second gas supply source 742, a second gas supply line 744, and a second valve 746.

The second gas supply source 742 may store the second gas. According to an embodiment, the second gas may be a gas excited in a plasma state. An end of the second gas supply line 744 may be connected to the second gas supply source 742, and the other end thereof may be connected to the gas channel described above. Accordingly, the second gas supply line 744 may supply the second gas to the gas channel. The second valve 746 is installed in the second gas supply line 744. The second valve 746 may be an on/off valve or a flow control valve. As described above, the second gas can be supplied to the edge region of the substrate W through a gas channel formed by a combination of the top edge electrode 510, the dielectric plate 310, the second base 520, and the first base 320.

In the embodiment described above, the chuck 210 moves in a vertical direction and positions of the dielectric plate 310 and the top edge electrode 510 are fixed, but the inventive concept is not limited thereto. For example, a position of the chuck 210 may be fixed, and the dielectric plate 310 may be configured to be movable in the vertical direction. In addition, both the chuck 210 and the dielectric plate 310 may be configured to be movable in the vertical direction.

In addition, in the above embodiment, it was described as an example that the edge electrode 250 and the top edge electrode 510 are grounded, respectively, but the inventive concept is not limited to this. Any one of the edge electrode 250 and the top edge electrode 510 may be grounded, and the other may be connected to an RF power source. In addition, both the edge electrode 250 and the top edge electrode 510 may be connected to the RF power source.

FIG. 4 schematically illustrates performing a plasma treatment process at the process chamber according to an embodiment of FIG. 2.

Referring to FIG. 4, the process chamber 60 according to an embodiment of the inventive concept may process the edge region of the substrate W by generating the plasma P in the edge region of the substrate W. For example, the process chamber 60 may perform a bevel etch process of treating the edge region of the substrate W.

When the substrate W is mounted on the top surface of the chuck 210, the gas supply unit 700 supplies the gas to the center region of the substrate W and the edge region of the substrate W. The second gas supplied through the gas channel may be excited in the plasma P state to treat the edge region of the substrate W. For example, the film formed in the edge region of the substrate W may be etched by the plasma P.

In addition, while treating the substrate W, gases flowing through in treating space 102 are uniformly exhausted to the outside of the treating space 102 through holes 256 formed at the protrusion portion 254, the separation space 104, and the exhaust hole 106. In a process of exhausting the gases, a uniformity of the gases flowing within the treating space 102 may be secured. In addition, by exhausting an atmosphere of the treating space 102 while treating the substrate W, a pressure in the treating space 102 can be uniformly controlled. Accordingly, the plasma may be uniformly generated in the treating space 102, particularly in the edge region of the substrate W.

In particular, according to an embodiment of the inventive concept, the protrusion portion 254 of the edge electrode 250 serving as a plasma source is formed integrally on the top portion of the body portion 252, so a region in which the plasma is generated in the treating space 102 can be efficiently limited. Accordingly, the plasma density generated in the edge region of the substrate W may be increased.

In addition, according to an embodiment of the inventive concept, the top surface of the body portion 252 and the top surface of the protrusion portion 254 are formed to correspond, so the plasma can be formed uniformly above the edge electrode 250. Specifically, since the protrusion portion 254 of the edge electrode 250 extends to the sidewall of the housing 100, the plasma can be generated to the sidewall of the housing 100. That is, the plasma may be generated from a region corresponding to the edge electrode 250 and the top edge electrode 510 to the sidewall of the housing 100. That is, the plasma may be formed in a high density in the lengthwise direction. Accordingly, the edge region of the substrate W may be treated using a high density and uniform plasma.

FIG. 5 to FIG. 10 schematically illustrate process chambers according to another embodiment of FIG. 1. Hereinafter, the process chambers according to an embodiment of the inventive concept will be described in detail with reference to FIG. 5 to FIG. 9. The process chamber 60 described below is mostly the same or similar to the configuration of the process chambers 60 described above, except for additional explanations, so the explanation of the overlapping configuration is omitted.

Referring to FIG. 5, the protrusion portion 254 according to an embodiment of the inventive concept can be integrally formed in a middle part of the body portion 252. Referring to FIG. 6, the protrusion portion 254 according to an embodiment of the inventive concept may be formed in a bottom part of the body portion 252. The body portion 252 is integrally formed with the protrusion portion 254.

According to an embodiment of the inventive concept described with reference to FIG. 5 and FIG. 6, since the protrusion portion 254 is formed in a central part or a bottom part of the body portion 252, a gas flow increases at a top side of the protrusion portion 254. Accordingly, the plasma density generated in the edge region of the substrate W may be relatively reduced than the process chamber 60 described with reference to FIG. 2 to FIG. 4. The process chamber 60 according to an embodiment of the inventive concept may be efficient if treating the substrate W with a plasma having a small density or if a thickness of a thin film on the substrate W to be etched is thin.

Referring to FIG. 7, the protrusion portion 254 according to an embodiment of the inventive concept may be integrally formed with the body portion 252. In addition, the protrusion portion 254 according to an embodiment of the inventive concept may be formed at a top end of the body portion 252. The top surface of the protrusion portion 254 may be formed to be spaced apart from the top surface of the body portion 252. For example, the top surface of the protrusion portion 254 may be formed at a relatively lower height than the top surface of the body portion 252. Referring to FIG. 8, the protrusion portion 254 according to an embodiment of the inventive concept may be integrally formed on the top end of the body portion 252. The top surface of the protrusion portion 254 may be formed to be spaced apart from the top surface of the body portion 252. For example, the top surface of the protrusion portion 254 may be formed to be stepped higher than the top surface of the body portion 252.

The process chamber 60 according to an embodiment of the inventive concept described with reference to FIG. 7 and FIG. 8 may be efficient when finely controlling the flow of gas in the edge region of the substrate W. Accordingly, the plasma density generated in the edge region of the substrate W may be efficiently controlled.

Referring to FIG. 9, the protrusion portion 254 according to an embodiment of the inventive concept may be integrally formed on the top end of the body portion 252. The top surface of the protrusion portion 254 may be formed to be inclined. That is, as shown in FIG. 9, the top surface of the protrusion portion 254 may be downwardly inclined toward the sidewall of the housing 100. In addition, an inner top end of the protrusion portion 254 may be formed at a height corresponding to an outer top end of the body portion 252. However, the inventive concept is not limited thereto, and an inner top end of the protrusion portion 254 may be formed to be stepped from the outer top end of the body portion 252.

Referring to FIG. 10, the protrusion portion 254 according to an embodiment of the inventive concept may be integrally formed with the body portion 252. In addition, the protrusion portion 254 may be formed at the top end of the body portion 252. The inner top end of the protrusion portion 254 may be formed at a height corresponding to the outer top end of the body portion 252. However, the inventive concept is not limited thereto, and the inner top end of the protrusion portion 254 may be formed to be stepped from the outer top end of the body portion 252. In addition, the top surface of the protrusion portion 254 may be formed to be upwardly inclined toward the side wall of the housing 100.

According to the embodiments described with reference to FIG. 7 to FIG. 10, a gas fluidity in the treating space 102, particularly in the edge region of the substrate W, may be modified to meet process requirements. Accordingly, the plasma density in the edge region of the substrate W may be appropriately changed.

In the embodiments described with reference to FIG. 7 to FIG. 10, it has been described that the protrusion portion 254 is formed on the top end of the body portion 252, but the inventive concept is not limited thereto. For example, the protrusion portion 254 according to the embodiment described in FIG. 7 to FIG. 10 may be formed in the top part, the middle part, or the bottom part of the body portion 252.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a housing having a treating space;
a support unit configured to support a substrate at the treating space; and
a gas supply unit configured to supply a gas which is excited to a plasma to the treating space, and
wherein the support unit includes:
a chuck supporting a center region of the substrate; and
an edge electrode formed in a ring shape, and
wherein the edge electrode includes:
a body portion surrounding the chuck at an outer side of the chuck; and
a protrusion portion formed protruding to an outer side of the body portion, and
a hole is formed at the protrusion portion penetrating the protrusion portion and which exhausts an atmosphere of the treating space.

2. The substrate treating apparatus of claim 1, wherein the protrusion portion and the body portion are formed integrally.

3. The substrate treating apparatus of claim 2, wherein the protrusion portion is formed along a circumferential direction of the body portion.

4. The substrate treating apparatus of claim 3, wherein an outer circumference of the protrusion portion extends to a sidewall of the housing.

5. The substrate treating apparatus of claim 4, wherein an exhaust hole is formed at the housing to exhaust the atmosphere of the treating space, and
the atmosphere of the treating space is exhausted while passing through the hole and the exhaust hole.

6. The substrate treating apparatus of claim 1, wherein a top surface of the protrusion portion is positioned at a same height as a top surface of the body portion.

7. The substrate treating apparatus of claim 1, wherein the protrusion portion is formed at a top end of the body portion, and
the top surface of the protrusion portion and the top end of the body portion are formed stepped with respect to one another.

8. The substrate treating apparatus of claim 7, wherein the top surface of the protrusion portion is positioned lower than the top surface of the body portion.

9. The substrate treating apparatus of claim 1, wherein the top surface of the protrusion portion is formed inclined.

10. The substrate treating apparatus of claim 9, wherein the top surface of the protrusion portion is formed downwardly inclined toward the sidewall of the housing.

11. A substrate treating apparatus comprising:
a housing having a treating space;
a support unit configured to support a substrate at the treating space; and
a plasma source for generating a plasma at an edge region of a substrate supported on the support unit, and
wherein the support unit includes:
a chuck supporting a center region of the substrate; and
an edge electrode formed in a ring shape and positioned below the edge region, and
wherein the edge electrode includes:
a body portion surrounding the chuck at an outer side of the chuck; and
a protrusion portion having a through hole for exhausting an atmosphere of the treating space and which protrudes to an outer side of the body portion.

12. The substrate treating apparatus of claim 11, wherein the protrusion portion and the body portion are formed integrally.

13. The substrate treating apparatus of claim 12, wherein a top surface of the protrusion portion is positioned at a height which is substantially the same as a top surface of the body portion.

14. The substrate treating apparatus of claim 12, wherein the top surface of the protrusion portion is positioned at a different height from the top surface of the body portion.

15. The substrate treating apparatus of claim 14, wherein the top surface of the protrusion portion is positioned lower than the top surface of the body portion.

16. The substrate treating apparatus of claim 12, wherein the top surface of the protrusion portion is formed inclined.

17. The substrate treating apparatus of claim 16, wherein the top surface of the protrusion portion is formed upwardly inclined toward the body portion.

18. The substrate treating apparatus of claim 11, wherein the plasma source includes a top edge electrode positioned above the edge region.

19. A substrate treating apparatus comprising:
a housing having a treating space;
a support unit configured to support a substrate at the treating space; and
a gas supply unit configured to supply a gas to an edge region of a substrate supported on the support unit; and
a top edge electrode positioned above the edge region, and
wherein the support unit includes:
a chuck supporting a center region of the substrate; and
an edge electrode formed in a ring shape and positioned below the edge region, and
wherein the edge electrode includes:
a body portion surrounding the chuck at an outer side of the chuck; and
a protrusion portion formed protruding to an outer side of the body portion, and
a hole which is formed at the protrusion portion penetrating the protrusion portion and which exhausts an atmosphere of the treating space.

20. The substrate treating apparatus of claim 19, wherein the protrusion portion and the body portion are formed integrally.
